(19) United States
(12) Patent Application Publication
(10) Pub. No.: US 2026/0096060 A1
(43) Pub. Date: Apr. 2, 2026

(54) INFORMATION HANDLING SYSTEM WITH HEAT PIPE EXTENDER FOR A LIQUID COOLING PLATE

(71) Applicant: DELL PRODUCTS L.P., Round Rock, TX (US)

(72) Inventors: James L. Petivan, III, Austin, TX (US); Michael Stumpf, Cedar Park, TX (US)

(21) Appl. No.: 18/900,764

(22) Filed: Sep. 29, 2024

(51) Int. Cl. H05K 7/20

(52) U.S. Cl. CPC H05K 7/20336; H05K 7/20154; H05K 7/20254; H05K 7/20272; H05K 7/20809

(57) ABSTRACT

A system includes a cooling distribution unit and an information handling system. The information handling system includes at least one electronic component disposed within a reliable zone away from any potential leaks. The information further includes a cooling plate in fluid communication with the cooling distribution unit. The cooling distribution unit selectively circulates liquid coolant through the cooling plate. Further, the cooling plate is disposed in an unreliable zone that is likely to experience one or more leaks.

### FIELD OF THE DISCLOSURE

The present disclosure generally relates to information handling systems, and more particularly relates to an information handling system having a heat pipe extender for a liquid cooling plate.

### BACKGROUND

As the value and use of information continues to increase, individuals and businesses seek additional ways to process and store information. One option is an information handling system. An information handling system generally processes, compiles, stores, or communicates information or data for business, personal, or other purposes. Technology and information handling needs and requirements can vary between different applications. Thus, information handling systems can also vary regarding what information is handled, how the information is handled, how much information is processed, stored, or communicated, and how quickly and efficiently the information can be processed, stored, or communicated. The variations in information handling systems allow information handling systems to be general or configured for a specific user or specific use such as financial transaction processing, airline reservations, enterprise data storage, or global communications. In addition, information handling systems can include a variety of hardware and software resources that can be configured to process, store, and communicate information and can include one or more computer systems, graphics interface systems, data storage systems, networking systems, and mobile communication systems.

Information handling systems can also implement various virtualized architectures. Data and voice communications among information handling systems may be via networks that are wired, wireless, or some combination.

### SUMMARY

A system is disclosed and includes a cooling distribution unit and an information handling system. The information handling system includes at least one electronic component disposed within a reliable zone away from any potential leaks. The information further includes a cooling plate in fluid communication with the cooling distribution unit. The cooling distribution unit selectively circulates liquid coolant through the cooling plate. Further, the cooling plate is disposed in an unreliable zone that is likely to experience one or more leaks.

### BRIEF DESCRIPTION OF THE DRAWINGS

It will be appreciated that for simplicity and clarity of illustration, elements illustrated in the Figures are not necessarily drawn to scale. For example, the dimensions of some elements may be exaggerated relative to other elements. Embodiments incorporating teachings of the present disclosure are shown and described with respect to the drawings herein, in which:

FIG. 1 is a block diagram of a computing system according to an embodiment of the present disclosure;

FIG. 2 is a block diagram of a computing system according to another embodiment of the present disclosure;

FIG. 3 is a block diagram of a computing system according to yet another embodiment of the present disclosure; and

FIG. 4 is a block diagram of a general information handling system according to an embodiment of the present disclosure.

The use of the same reference symbols in different drawings indicates similar or identical items.

### DETAILED DESCRIPTION OF THE DRAWINGS

The following description in combination with the Figures is provided to assist in understanding the teachings disclosed herein. The description is focused on specific implementations and embodiments of the teachings and is provided to assist in describing the teachings. This focus should not be interpreted as a limitation on the scope or applicability of the teachings.

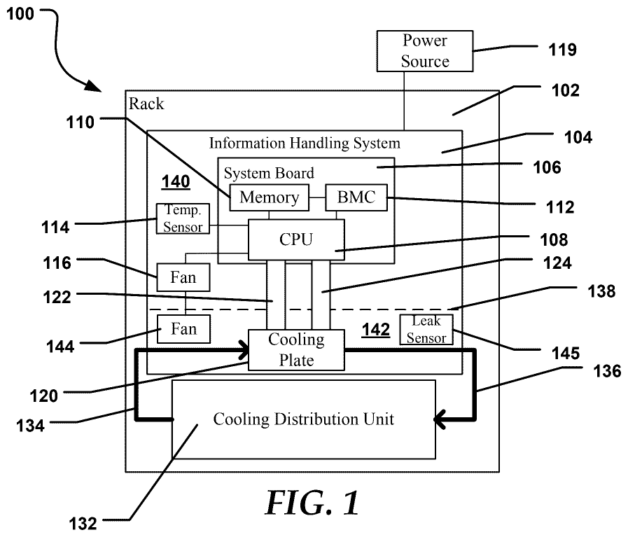

FIG. 1 illustrates a system 100 that may include a rack or cabinet 102 in which an inverted information handling system 104 is installed or otherwise disposed. For purposes of this disclosure, an information handling system can include any instrumentality or aggregate of instrumentalities operable to compute, calculate, determine, classify, process, transmit, receive, retrieve, originate, switch, store, display, communicate, manifest, detect, record, reproduce, handle, or utilize any form of information, intelligence, or data for business, scientific, control, or other purposes. For example, an information handling system may be a personal computer (such as a desktop or laptop), tablet computer, mobile device (such as a personal digital assistant (PDA) or smart phone), server (such as a blade server or rack server), a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, touchscreen and/or a video display. The information handling system may also include one or more buses operable to transmit communications between the various hardware components.

As shown, the information handling system 104 may include a system board or motherboard 106 that may have several electronic components disposed thereon or coupled thereto. For example the system board 106 may include a central processing unit (CPU) 108 installed, or otherwise disposed, thereon. The information handling system 104 may also include a memory 110 coupled to the CPU 108. Moreover, a baseboard management controller 112 may be disposed on the system board 106 and may be coupled to the CPU 108 and the memory 110. Other components necessary to the operation of the information handling system 104, and well known in the art, may be disposed on the system board 106. The information handling system 104 may also include a temperature sensor 114 and a first fan 116 adjacent the CPU 108. Additionally, the information handling system 104 may be coupled to a power source 119. The power source 119 may be an alternating current (AC) power source, a direct current (DC) power source, or a combination thereof. The power source 119 may provide power to all of the components described herein that required power to operate.

FIG. 1 further shows a cooling plate 120 near from the system board 106. Specifically, the cooling plate 120 is near the CPU 108 that may generate and emit a substantial amount of heat during operation of the information handling system 102. In a particular embodiment while the cooling plate 120 is near the CPU 108, it is spaced a predetermined distance from the CPU 108 and is coupled to the CPU 108 by heat pipes 122 and heat pipes 124. The heat pipes 122, 124 may conduct heat away from the CPU 108 to the cooling plate 120. Further the heat pipes 122, 124 may have fins.

A cooling distribution unit 132 may be connected to the cooling plate 130 via a coolant supply line 134 and a coolant return line 136. The cooling distribution unit 132 is in fluid communication with the cooling plate 130 via the coolant supply line 134 and the coolant return line 136. During operation the cooling distribution unit 132 may circulate coolant to the cooling plate 130 via the coolant supply line 134 and the coolant return line 136 in order to lower the temperature of the cooling plate 130, and therefore transfer heat generated by the CPU 108 away from the CPU 108 and the system board 106 in order to lower the operating temperature of the CPU 108, the system board 106, and the other components disposed on the system board 106.

As shown in FIG. 1, within the information handling system 104 the cooling plate 120 is spaced apart from the system board 106, the CPU 108, and other critical components that are at risk of being damaged in the event of a liquid coolant leak from the cooling plate 120. A barrier 138 may separate the cooling plate 120 from the system board 106, the CPU 108, and other critical components within the information handling system 104 that are at risk of being damaged in the event of a liquid coolant leak from the cooling plate 120. Thus, within the information handling system 104 a reliable zone 140 and a separate, unreliable zone 142 are established. The unreliable zone 142 is likely to have a liquid leak, while the reliable zone 140 is not likely to have a liquid leak. The first fan 116 is in the reliable zone 140 to provide air flow across the heat pipes 122, 124. A second fan 144 is located in the unreliable zone 142 to provide air flow across the cooling plate 120. Moreover, a leak sensor 145, e.g., an optical leak sensor, is disposed within the unreliable zone 142.

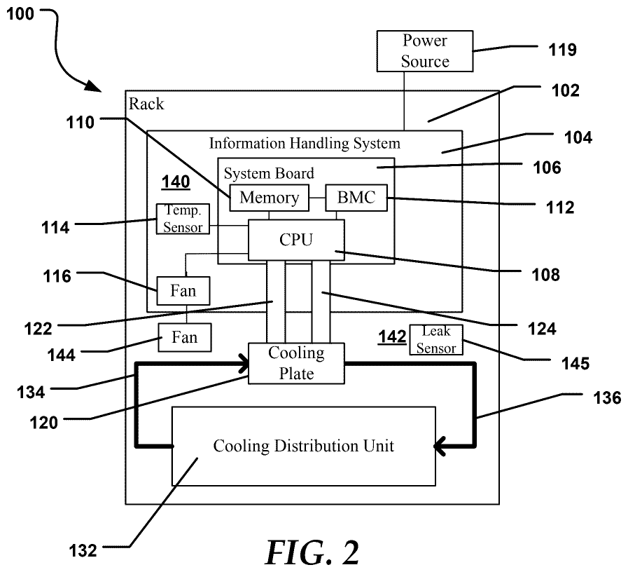

In another embodiment, as illustrated in FIG. 2, the cooling plate 120, the cooling distribution unit 132, and the second fan 144 may be located outside of the information handling system 104, but within the rack 102, such that the housing of the information handling system 104 may provide a barrier between the parts that are likely to leak fluid, e.g., the cooling plate 120. As such, the reliable zone 140 is within the information handling system 104 and the unreliable zone 142 is outside of the information handling system 104. Both zones are within the same rack 102.

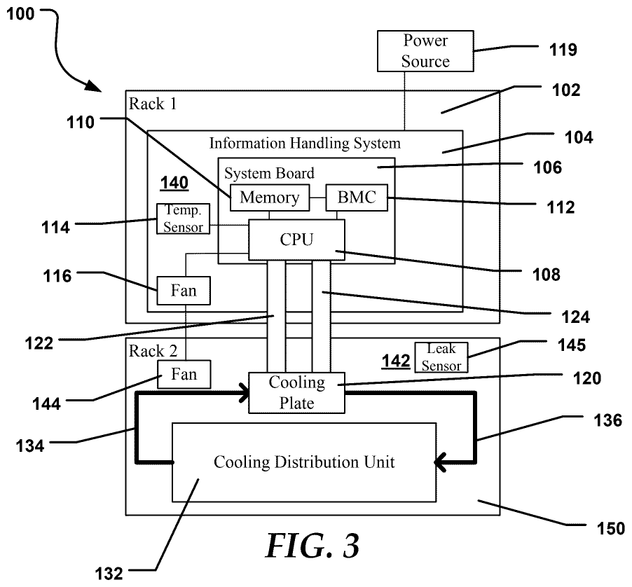

In still another embodiment, as shown in FIG. 3, the cooling plate 120, the cooling distribution unit 132, and the second fan 144 may be located outside of the information handling system 104, within a second rack 150 that is separate from the first rack 102. As such, the housing of the information handling system 104 and the racks 102, 150 may provide even greater barriers between the parts that are likely to leak fluid, e.g., the cooling plate 120. As such, the reliable zone 140 is within the information handling system 104 inside the first rack 102 and the unreliable zone 142 is outside of the information handling system 104 within the second rack 150. In each embodiment describe above, any leaks are substantially isolated from the critical electronic components.

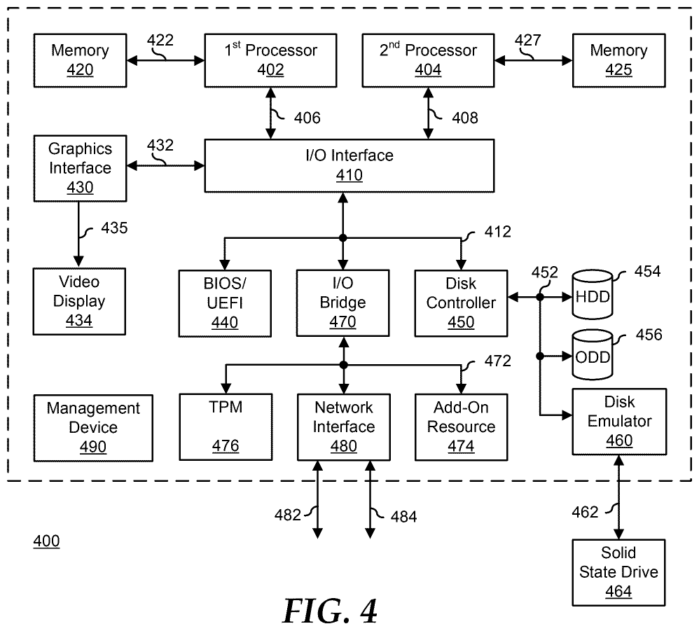

FIG. 4 shows a generalized embodiment of an information handling system 400 according to an embodiment of the present disclosure. Information handling system 400 may be substantially similar to the information handling system 104 of FIG. 1, FIG. 2, or FIG. 3. For purpose of this disclosure an information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 400 can be a personal computer, a laptop computer, a smart phone, a tablet device or other consumer electronic device, a network server, a network storage device, a switch router or other network communication device, or any other suitable device and may vary in size, shape, performance, functionality, and price. Further, information handling system 400 can include processing resources for executing machine-executable code, such as a central processing unit (CPU), a programmable logic array (PLA), an embedded device such as a System-on-a-Chip (SoC), or other control logic hardware. Information handling system 400 can also include one or more computer-readable medium for storing machine-executable code, such as software or data. Additional components of information handling system 400 can include one or more storage devices that can store machine-executable code, one or more communications ports for communicating with external devices, and various input and output (I/O) devices, such as a keyboard, a mouse, and a video display. Information handling system 400 can also include one or more buses operable to transmit information between the various hardware components.

Information handling system 400 can include devices or modules that embody one or more of the devices or modules described below and operates to perform one or more of the methods described herein. Information handling system 400 includes a processors 402 and 404, an input/output (I/O) interface 410, memories 420 and 425, a graphics interface 430, a basic input and output system/universal extensible firmware interface (BIOS/UEFI) module 440, a disk controller 450, a hard disk drive (HDD) 454, an optical disk drive (ODD) 456, a disk emulator 460 connected to an external solid state drive (SSD) 464, an I/O bridge 470, one or more add-on resources 474, a trusted platform module (TPM) 476, a network interface 480, a management device 490, and a power supply 495. Processors 402 and 404, I/O interface 410, memory 420, graphics interface 430, BIOS/UEFI module 440, disk controller 450, HDD 454, ODD 456, disk emulator 460, SSD 464, I/O bridge 470, add-on resources 474, TPM 476, and network interface 480 operate together to provide a host environment of information handling system 400 that operates to provide the data processing functionality of the information handling system. The host environment operates to execute machine-executable code, including platform BIOS/UEFI code, device firmware, operating system code, applications, programs, and the like, to perform the data processing tasks associated with information handling system 400.

In the host environment, processor 402 is connected to I/O interface 410 via processor interface 406, and processor 404 is connected to the I/O interface via processor interface 408. Memory 420 is connected to processor 402 via a memory interface 422. Memory 425 is connected to processor 404 via a memory interface 427. Graphics interface 430 is connected to I/O interface 410 via a graphics interface 432 and provides a video display output 436 to a video display 434. In a particular embodiment, information handling system 400 includes separate memories that are dedicated to each of processors 402 and 404 via separate memory interfaces. An example of memories 420 and 430 include random access memory (RAM) such as static RAM (SRAM), dynamic RAM (DRAM), non-volatile RAM (NV-RAM), or the like, read only memory (ROM), another type of memory, or a combination thereof.

BIOS/UEFI module 440, disk controller 450, and I/O bridge 470 are connected to I/O interface 410 via an I/O channel 412. An example of I/O channel 412 includes a Peripheral Component Interconnect (PCI) interface, a PCI-Extended (PCI-X) interface, a high-speed PCI-Express (PCIe) interface, another industry standard or proprietary communication interface, or a combination thereof. I/O interface 410 can also include one or more other I/O interfaces, including an Industry Standard Architecture (ISA) interface, a Small Computer Serial Interface (SCSI) interface, an Inter-Integrated Circuit (I²C) interface, a System Packet Interface (SPI), a Universal Serial Bus (USB), another interface, or a combination thereof. BIOS/UEFI module 440 includes BIOS/UEFI code operable to detect resources within information handling system 400, to provide drivers for the resources, initialize the resources, and access the resources. BIOS/UEFI module 440 includes code that operates to detect resources within information handling system 400, to provide drivers for the resources, to initialize the resources, and to access the resources.

Disk controller 450 includes a disk interface 452 that connects the disk controller to HDD 454, to ODD 456, and to disk emulator 460. An example of disk interface 452 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 460 permits SSD 464 to be connected to information handling system 400 via an external interface 462. An example of external interface 462 includes a USB interface, an IEEE 4394 (Firewire) interface, a proprietary interface, or a combination thereof. Alternatively, solid-state drive 464 can be disposed within information handling system 400.

I/O bridge 470 includes a peripheral interface 472 that connects the I/O bridge to add-on resource 474, to TPM 476, and to network interface 480. Peripheral interface 472 can be the same type of interface as I/O channel 412 or can be a different type of interface. As such, I/O bridge 470 extends the capacity of I/O channel 412 when peripheral interface 472 and the I/O channel are of the same type, and the I/O bridge translates information from a format suitable to the I/O channel to a format suitable to the peripheral channel 472 when they are of a different type. Add-on resource 474 can include a data storage system, an additional graphics interface, a network interface card (NIC), a sound/video processing card, another add-on resource, or a combination thereof. Add-on resource 474 can be on a main circuit board, on separate circuit board or add-in card disposed within information handling system 400, a device that is external to the information handling system, or a combination thereof.

Network interface 480 represents a NIC disposed within information handling system 400, on a main circuit board of the information handling system, integrated onto another component such as I/O interface 410, in another suitable location, or a combination thereof. Network interface device 480 includes network channels 482 and 484 that provide interfaces to devices that are external to information handling system 400. In a particular embodiment, network channels 482 and 484 are of a different type than peripheral channel 472 and network interface 480 translates information from a format suitable to the peripheral channel to a format suitable to external devices. An example of network channels 482 and 484 includes InfiniBand channels, Fibre Channel channels, Gigabit Ethernet channels, proprietary channel architectures, or a combination thereof. Network channels 482 and 484 can be connected to external network resources (not illustrated). The network resource can include another information handling system, a data storage system, another network, a grid management system, another suitable resource, or a combination thereof.

Management device 490 represents one or more processing devices, such as a dedicated baseboard management controller (BMC) System-on-a-Chip (SoC) device, one or more associated memory devices, one or more network interface devices, a complex programmable logic device (CPLD), and the like, which operate together to provide the management environment for information handling system 400. In particular, management device 490 is connected to various components of the host environment via various internal communication interfaces, such as a Low Pin Count (LPC) interface, an Inter-Integrated-Circuit (I2C) interface, a PCIe interface, or the like, to provide an out-of-band (OOB) mechanism to retrieve information related to the operation of the host environment, to provide BIOS/UEFI or system firmware updates, to manage non-processing components of information handling system 400, such as system cooling fans and power supplies. Management device 490 can include a network connection to an external management system, and the management device can communicate with the management system to report status information for information handling system 400, to receive BIOS/UEFI or system firmware updates, or to perform other task for managing and controlling the operation of information handling system 400.

Management device 490 can operate off of a separate power plane from the components of the host environment so that the management device receives power to manage information handling system 400 when the information handling system is otherwise shut down. An example of management device 490 include a commercially available BMC product or other device that operates in accordance with an Intelligent Platform Management Initiative (IPMI) specification, a Web Services Management (WSMan) interface, a Redfish Application Programming Interface (API), another Distributed Management Task Force (DMTF), or other management standard, and can include an Integrated Dell Remote Access Controller (iDRAC), an Embedded Controller (EC), or the like. Management device 490 may further include associated memory devices, logic devices, security devices, or the like, as needed, or desired.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

What is claimed is:

1. A system comprising:
a cooling distribution unit;
an information handling system including:
at least one electronic component disposed within a reliable zone away from any potential leaks; and
a cooling plate in fluid communication with the cooling distribution unit, wherein the cooling distribution unit selectively circulates liquid coolant through the cooling plate and wherein the cooling plate is disposed in an unreliable zone that is likely to experience one or more leaks.

2. The system of claim 1, further comprising:
a heat pipe connecting the at least one electronic component to the cooling plate, wherein the heat pipe extends between the reliable zone and the unreliable zone.

3. The system of claim 2, further comprising:
a first fan within the reliable zone to provide airflow across the heat pipe.

4. The system of claim 3, further comprising:
a second fan within the unreliable zone to provide airflow across the cooling plate.

5. The system of claim 1, further comprising:
a leak detector within the unreliable zone.

6. The system of claim 1, wherein the reliable zone and the unreliable zone are located within the information handling system and separated by a barrier.

7. The system of claim 1, wherein the reliable zone is located within a housing of the information handling system and the unreliable zone is located outside of the housing of the information handling system.

8. The system of claim 1, wherein the reliable zone is located within a housing of the information handling system within a first rack and the unreliable zone is located outside of the housing of the information handling system within a second rack.

9. A system, comprising:
a cooling distribution unit within an unreliable zone that is likely to experience liquid leaks;
a cooling plate in fluid communication with a cooling distribution unit within the unreliable zone, wherein the cooling distribution unit selectively circulates liquid coolant through the cooling plate wherein the cooling plate is spaced apart a distance from the processor; and
an information handling system having a processor within a reliable zone that is substantially free of liquid leaks.

10. The system of claim 9, further comprising:
a heat pipe connecting the processor to the cooling plate and extending between the reliable zone and the unreliable zone.

1. The system of claim 10, further comprising:
a first fan within the reliable zone to provide airflow across the heat pipe.

12. The system of claim 11, further comprising:
a second fan within the unreliable zone to provide airflow across the cooling plate.

2. The system of claim 12, further comprising:
a leak detector within the unreliable zone.

14. The system of claim 9, wherein the reliable zone and the unreliable zone are located within the information handling system and separated by a barrier.

15. The system of claim 9, wherein the reliable zone is located within a housing of the information handling system and the unreliable zone is located outside of the housing of the information handling system.

16. The system of claim 9, wherein the reliable zone is located within a housing of the information handling system within a first rack and the unreliable zone is located outside of the housing of the information handling system within a second rack.

17. A system comprising:
a reliable zone that is substantially free of liquid leaks;
an unreliable zone that is likely to experience liquid leaks;
a cooling distribution unit within the unreliable zone;
a cooling plate in fluid communication with a cooling distribution unit within the unreliable zone, wherein the cooling distribution unit selectively circulates liquid coolant through the cooling plate wherein the cooling plate is spaced apart a distance from the processor;
an information handling system having a processor and a memory within the reliable zone; and
a heat pipe connecting the processor to the cooling plate and extending between the reliable zone and the unreliable zone.

18. The system of claim 17, wherein the reliable zone and the unreliable zone are located within the information handling system and separated by a barrier.

19. The system of claim 18, wherein the reliable zone is located within a housing of the information handling system and the unreliable zone is located outside of the housing of the information handling system.

20. The system of claim 18, wherein the reliable zone is located within a housing of the information handling system within a first rack and the unreliable zone is located outside of the housing of the information handling system within a second rack.
